(19) United States
(12) Patent Application Publication
(10) Pub. No.: US 2024/0063070 A1
(43) Pub. Date: Feb. 22, 2024

(54) METHOD OF MANUFACTURING SEMICONDUCTOR PACKAGE

(71) Applicant: SAMSUNG ELECTRONICS CO., LTD., Suwon-si (KR)

(72) Inventors: Youngchan Ko, Suwon-si (KR); Byungho Kim, Suwon-si (KR); Yongkoon Lee, Suwon-si (KR)

(73) Assignee: SAMSUNG ELECTRONICS CO., LTD., Suwon-si (KR)

(21) Appl. No.: 18/231,363

(22) Filed: Aug. 8, 2023

(30) Foreign Application Priority Data
Aug. 16, 2022 (KR) 10-2022-0102229

(51) Int. Cl. H01L 23/31; H01L 23/00; H01L 25/065; H01L 21/56

(52) U.S. Cl. CPC H01L 23/3121; H01L 24/16; H01L 25/0657; H01L 21/565; H01L 2224/16225; H01L 2225/06541; H01L 2924/3511

(57) ABSTRACT

A method of manufacturing a semiconductor package, the method including forming a first solder ball on a surface of a redistribution layer, forming a preliminary molding layer on the surface of the redistribution layer and the first solder ball, exposing the first solder ball by grinding the preliminary molding layer and the first solder ball, and forming a second solder ball by reflowing the first solder ball, wherein the second solder ball is spaced apart from the molding layer, in a horizontal direction.

### CROSS-REFERENCE TO RELATED APPLICATION

This application is based on and claims priority under 35 U. S. C. § 119 to Korean Patent Application No. 10-2022-0102229, filed on Aug. 16, 2022, in the Korean Intellectual Property Office, the disclosure of which is incorporated by reference herein in its entirety.

### BACKGROUND

The present disclosure relates to a method of manufacturing a semiconductor package.

In accordance with the rapid development of the electronics industry and user demand, electronic devices have become miniaturized, more multifunctional, and larger in capacity.

As a result, a semiconductor package with an increased number of input/output (I/O) connection terminals (I/O terminals) has been designed, and for example, a fan-out type semiconductor package has been developed to prevent interference between connection terminals.

### SUMMARY

Example embodiments provide a method of manufacturing a fan-out type semiconductor package having structural reliability.

According to an aspect of an example embodiment, a method of manufacturing a semiconductor package includes: forming a first solder ball on a surface of a redistribution layer; forming a preliminary molding layer on the surface of the redistribution layer and the first solder ball; exposing the first solder ball and forming a molding layer by grinding the preliminary molding layer and the first solder ball; and forming a second solder ball by reflowing the first solder ball, wherein the second solder ball is spaced apart from the molding layer in a horizontal direction.

According to an aspect of an example embodiment, a method of manufacturing a semiconductor package includes: attaching at least one semiconductor chip to a carrier substrate; forming an intermediate layer covering an upper surface of the at least one semiconductor chip; removing the carrier substrate; forming a lower redistribution layer on a lower portion of the at least one semiconductor chip; forming an upper redistribution layer on an upper portion of the intermediate layer; forming a first solder ball on the lower redistribution layer; forming a preliminary molding layer on a lower surface of the lower redistribution layer and on the first solder ball; grinding the preliminary molding layer and the first solder ball; applying a solder paste on the first solder ball; and forming a second solder ball by reflowing the first solder ball and the solder paste, wherein a volume of the second solder ball is less than a volume of the first solder ball.

According to an aspect of an example embodiment, a method of manufacturing a semiconductor package includes: forming a first structure comprising a first semiconductor chip and a plurality of second semiconductor chips stacked on the first semiconductor chip; forming a second structure spaced apart from the first structure in a horizontal direction, wherein the second structure comprises a third semiconductor chip; attaching the first structure and the second structure to an interposer; forming a first molding layer and a first solder ball on a lower surface of the interposer; attaching the interposer to a package base substrate; forming a second molding layer and a second solder ball on a lower surface of the package base substrate, wherein each of the first molding layer and the second molding layer comprises an epoxy molding compound (EMC), wherein the first solder ball is spaced apart from the first molding layer in a horizontal direction, and wherein the second solder ball is spaced apart from the second molding layer in the horizontal direction.

### BRIEF DESCRIPTION OF THE DRAWINGS

The above and other aspects and features will be more apparent from the following description of example embodiments taken in conjunction with the accompanying drawings, in which:

FIG. 1 is a cross-sectional view of a semiconductor package according to an example embodiment;

FIG. 2 is a diagram illustrating a first solder ball, a second solder ball, and a third solder ball in an operation of manufacturing a semiconductor package according to an example embodiment;

FIG. 3 is a diagram illustrating a bottom surface of a semiconductor package according to an example embodiment;

FIGS. 4, 5, 6, 7, 8, 9, 10 and 11 are cross-sectional views of a method of manufacturing a semiconductor package, according to an example embodiment;

FIGS. 12 and 13 are diagrams illustrating an effect of preventing a warpage phenomenon according to a coefficient of thermal expansion (CTE) of a molding layer of a semiconductor package, according to an example embodiment;

FIG. 14 is a flowchart illustrating a method of manufacturing a semiconductor package, according to an example embodiment;

FIG. 15 is a cross-sectional view of a semiconductor package according to an example embodiment; and

FIG. 16 is a cross-sectional view of a semiconductor package according to an example embodiment.

### DETAILED DESCRIPTION

Example embodiments will be described in detail below with reference to the accompanying drawings. Like components are denoted by like reference numerals throughout the specification, and repeated descriptions thereof are omitted.

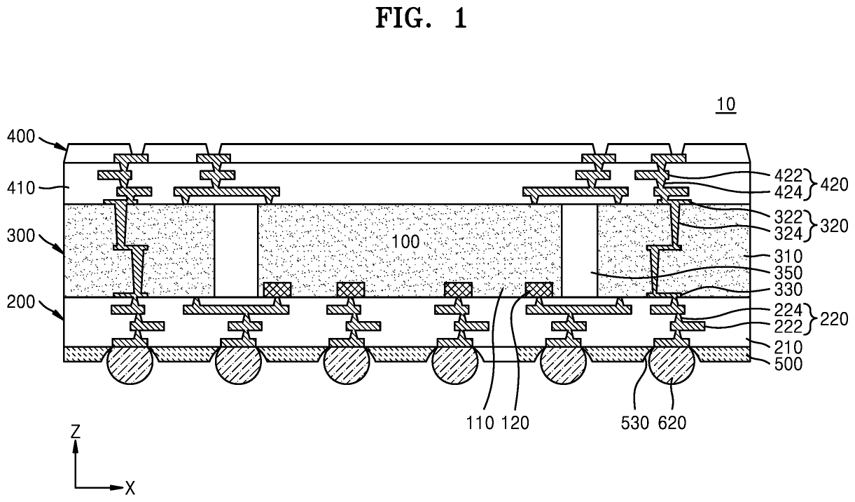

FIG. 1 is a cross-sectional view of a semiconductor package 10 according to an example embodiment.

Referring the example embodiment shown in to FIG. 1, the semiconductor package 10 may include a lower redistribution layer 200, an intermediate layer 300 on the lower redistribution layer 200, at least one semiconductor chip 100 in the intermediate layer 300, and an upper redistribution layer 400 on the intermediate layer 300.

The semiconductor package 10 may be a fan-out type semiconductor package having a greater horizontal width and horizontal area of the lower redistribution layer 200 than a horizontal width and horizontal area of a footprint formed by the at least one semiconductor chip 100. In some example embodiments, the semiconductor package 10 may be a fan-out type wafer level package (FOWLP) or a fan-out type panel level package (FOPLP).

Herein, the semiconductor package 10 is described as including one semiconductor chip 100, but this is an example embodiment, and example embodiments are not limited thereto. For example, the semiconductor package 10 may include at least one semiconductor chip, and the number of semiconductor chips included in the semiconductor package 10 is not limited.

The semiconductor chip 100 may include a semiconductor substrate 110. The semiconductor chip 100 may include a plurality of chip connection pads 120, which are on an active surface of the semiconductor substrate 110. The semiconductor substrate 110 and the active surface of the semiconductor substrate 110 may be respectively referred to as a first semiconductor substrate and a first active surface thereof. The semiconductor chip 100 may be arranged on the lower redistribution layer 200 such that the active surface of the semiconductor substrate 110 faces the lower redistribution layer 200. For example, the semiconductor chip 100 may be arranged on the lower redistribution layer 200 such that each of the plurality of chip connection pads 120 faces the lower redistribution layer 200.

The semiconductor substrate 110 may include a semiconductor material, including, but not limited to, silicon (Si). Alternatively, the semiconductor substrate 110 may include a semiconductor element, including, but not limited to, germanium (Ge), or a compound semiconductor, including, but not limited to, silicon carbide (SiC), gallium arsenide (GaAs), indium arsenide (InAs), and indium phosphide (InP). The semiconductor substrate 110 may include a conductive region, for example, a doped well. The semiconductor substrate 110 may have various device isolation structures, including, but not limited to, a shallow trench isolation (STI) structure.

A semiconductor device including a plurality of individual devices of various types may be formed on the active surface of the semiconductor substrate 110. The plurality of individual devices may include various microelectronic devices, for example, a metal-oxide-semiconductor field effect transistor (MOSFET) (e.g., a complementary metal-insulator-semiconductor (CMOS) transistor), a system large-scale integration (LSI), an image sensor (e.g., a CMOS imaging sensor (CIS)), a micro-electro-mechanical system (MEMS), an active device, and a passive device, or the like. The plurality of individual devices may be electrically connected to the conductive region of the semiconductor substrate 110. In addition, each of the plurality of individual devices may be electrically isolated from other neighboring individual devices by an insulating film.

The semiconductor chip 100 may be, for example, a processor chip, a power management integrated circuit (PMIC) chip, or a memory chip. The processor chip may be a central processing unit (CPU) chip, a graphics processing unit (GPU) chip, or an application processor (AP) chip. The memory chip may be a dynamic random access memory (DRAM) chip, a static RAM (SRAM) chip, a flash memory chip, an electrically erasable and programmable read-only memory (EEPROM) chip, a phase-change random access memory (PRAM) chip, a magnetic random access memory (MRAM) chip, and a resistive random access memory (RRAM) chip, or the like.

In some example embodiments, the plurality of chip connection pads 120 may each include aluminum (Al) or an alloy including Al.

The lower redistribution layer 200 may include at least one lower redistribution insulating layer 210, and a lower redistribution conductive structure 220. The at least one lower redistribution insulating layer 210 may surround at least a portion of the lower redistribution conductive structure 220. The lower redistribution conductive structure 220 may include a plurality of lower redistribution line patterns 222, which contact at least one of an upper surface and a lower surface of the at least one lower redistribution insulating layer 210, and a plurality of lower redistribution via patterns 224, which pass through at least some of the at least one lower redistribution insulating layer 210 and are respectively in contact with, and connected to, some of the plurality of lower redistribution line patterns 222. The lower redistribution conductive structure 220 may be connected between an expansion structure 310 and a second solder ball 620.

The plurality of lower redistribution line patterns 222 may form a plurality of redistribution layers by being positioned at two or more different vertical levels. Herein, a redistribution layer may mean, but is not limited to, a location having a circuit wire configured to form an electrical path on the same plane. Herein, a redistribution layer may mean a location where some of the plurality of lower redistribution line patterns 222 are arranged on the same plane to form an electrical path, and the plurality of redistribution layers may mean that some different lower redistribution line patterns 222 are arranged on respective planes at different vertical levels to form electrical paths, respectively. The plurality of lower redistribution via patterns 224 may electrically connect the lower redistribution line patterns 222, which are positioned in different redistribution layers, to each other.

Each of the lower redistribution line patterns 222 and the lower redistribution via patterns 224 may include a metal, including, but not limited to, copper (Cu), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or the like, or an alloy thereof.

At least some of the plurality of lower redistribution line patterns 222 may be integrally formed with some of the plurality of lower redistribution via patterns 224. For example, some of the plurality of lower redistribution line patterns 222 may be integrally formed with some of the plurality of lower redistribution via patterns 224, which are in contact with upper sides of some of the plurality of lower redistribution line patterns 222.

In some example embodiments, the plurality of lower redistribution via patterns 224 may each have a tapered shape, wherein a horizontal width is reduced from a lower side to an upper side thereof. For example, the horizontal width of each of the plurality of lower redistribution via patterns 224 may increase in a direction moving away from the semiconductor chip 100. In some example embodiments, the horizontal width of each of the plurality of lower redistribution via patterns 224 may be reduced in a direction away from some of the plurality of lower redistribution line patterns 222, which are integrally formed with some of the plurality of lower redistribution via patterns 224.

The at least one lower redistribution insulating layer 210 may be formed from, for example, a material film including an organic compound. In some example embodiments, the at least one lower redistribution insulating layer 210 may be formed from a material film including an organic polymer material. In some example embodiments, the at least one lower redistribution insulating layer 210 may be formed from photosensitive polyimide (PSPI).

The intermediate layer 300 may include the semiconductor chip 100, the expansion structure 310, a via structure 320, and a connection pad 330. The connection pad 330 may be on the lower redistribution layer 200, the expansion structure 310 may cover the connection pad 330 on the lower redistribution layer 200, and the via structure 320 may be connected to the connection pad 330 by penetrating through the expansion structure 310.

The expansion structure 310 may be, but is not limited to, a printed circuit board (PCB), a ceramic substrate, a package-manufacturing wafer, an interposer, or a molding layer including a molding material. In some example embodiments, the intermediate layer 300 may be a multi-layered PCB. A mounting space of the intermediate layer 300 may be formed as an opening portion or a cavity in the intermediate layer 300. The semiconductor chip 100 may be accommodated in the mounting space of the intermediate layer 300. The mounting space may be formed in a partial region (e.g., a central region) of the intermediate layer 300. The mounting space may be recessed or opened to a certain depth from an upper surface of the intermediate layer 300. To recess or open the intermediate layer 300, a dry etching process, a wet etching process, a screen print process, a drill bit process, a laser drilling process, or the like, may be used.

The expansion structure 310 may include at least one material selected from phenol resin, epoxy resin, and polyimide. The expansion structure 310 may include, for example, at least one material selected from frame retardant 4 (FR-4), tetrafunctional epoxy, polyphenylene ether, epoxy/polyphenylene oxide, bismaleimide triazine (BT), thermount, cyanate ester, polyimide, and a liquid crystal polymer, or may include an epoxy mold compound (EMC).

The via structure 320 may include a via connection pad unit 322 and an extension via unit 324. The via connection pad unit 322 may be on an upper surface of the expansion structure 310, and the extension via unit 324 may connect the via connection pad unit 322 and the connection pad 330 to each other by penetrating through the expansion structure 310. In some example embodiments, the lowermost surface of the connection pad 330 and the lower surface of the expansion structure 310 may be positioned on the same vertical level to form a coplanar surface. For example, the connection pad 330 may be embedded in the expansion structure 310. The via structure 320 and the connection pad 330 may each include Cu or an alloy including Cu.

In some example embodiments, the expansion structure 310 may be a multi-layered substrate including a plurality of layers. When the expansion structure 310 includes a plurality of layers, the intermediate layer 300 may include a plurality of via structures 320 respectively corresponding to the plurality of layers of the expansion structure 310. For example, the plurality of via structures 320 may be vertically stacked by passing through the plurality of layers of the expansion structure 310.

The intermediate layer 300 may further include a sealing layer 350 filling the mounting space thereof. The sealing layer 350 may fill a space between the semiconductor chip 100 and the expansion structure 310. The sealing layer 350 may fill a space between the semiconductor chip 100 and the expansion structure 310, and cover upper surfaces of the semiconductor chip 100 and the expansion structure 310.

The semiconductor package 10 may further include the upper redistribution layer 400 on the sealing layer 350. The upper redistribution layer 400 may include at least one upper redistribution insulating layer 410 and an upper redistribution conductive structure 420. The upper redistribution conductive structure 420 may include a plurality of upper redistribution line patterns 422 contacting at least one of an upper surface and a lower surface of the at least one upper redistribution insulating layer 410, and a plurality of upper redistribution via patterns 424, which pass through at least a portion of the at least one upper redistribution insulating layer 410 and are respectively in contact with, and connected to, some of the plurality of upper redistribution line patterns 422. The upper redistribution conductive structure 420 may be connected to the via connection pad unit 322 of the via structure 320.

The upper redistribution insulating layer 410 and the upper redistribution conductive structure 420 including the plurality of upper redistribution line patterns 422 and the plurality of upper redistribution via patterns 424, which are included in the upper redistribution layer 400, may be respectively and substantially similar to the lower redistribution insulating layer 210 and the lower redistribution conductive structure 220, including the plurality of lower redistribution line patterns 222 and the plurality of lower redistribution via patterns 224, which are included in the lower redistribution layer 200, and thus, repeated descriptions thereof are omitted.

At least some of the plurality of upper redistribution line patterns 422 may be integrally formed with some of the plurality of upper redistribution via patterns 424. For example, some of the plurality of upper redistribution line patterns 422 may be integrally formed with some of the plurality of upper redistribution via patterns 424, which are in contact with lower sides of some of the plurality of upper redistribution line patterns 422.

In some example embodiments, the plurality of upper redistribution via patterns 424 may each have a tapered shape wherein a horizontal width increases from a lower side to an upper side thereof. For example, the horizontal width of each of the plurality of upper redistribution via patterns 424 may increase in a direction moving away from the semiconductor chip 100. In some example embodiments, the horizontal width of each of the plurality of upper redistribution via patterns 424 may be reduced in a direction moving away from some of the plurality of upper redistribution line patterns 422, which are integrally formed with some of the plurality of upper redistribution via patterns 424.

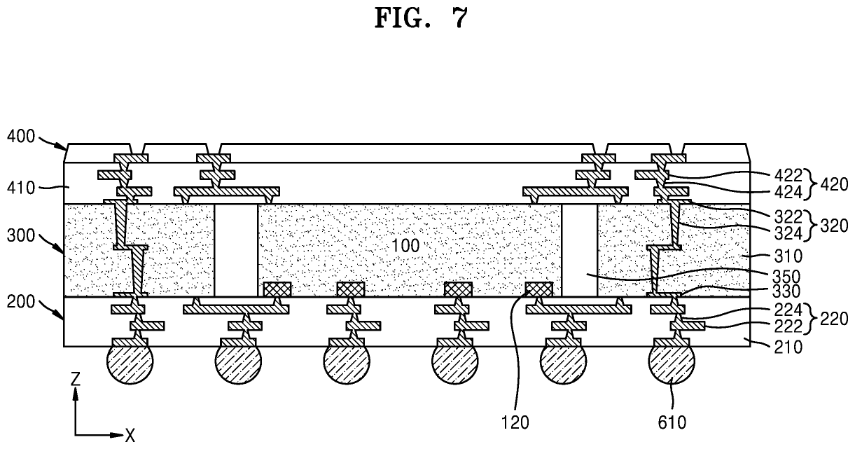

At least a portion of the second solder ball 620 may be formed by reflowing a portion of a first solder ball 610 according to the example embodiment shown in FIG. 7. The first solder ball 610 and the second solder ball 620 may each have a circular shape or an oval shape. The first solder ball 610 and the second solder ball 620 may each be formed of any one selected from eutectic solder, high lead solder, and lead-free solder, but example embodiments are not limited thereto.

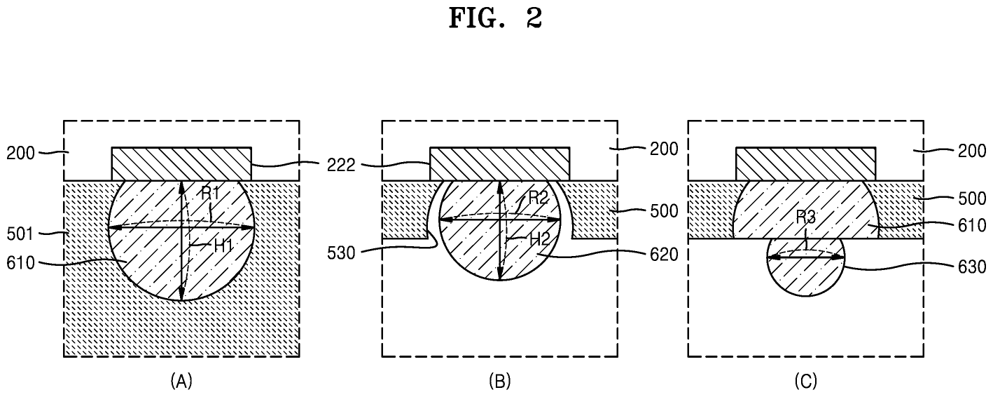

FIG. 2 is a diagram illustrating the first solder ball 610, the second solder ball 620, and a third solder ball 630 in an operation of manufacturing a semiconductor package according to an example embodiment.

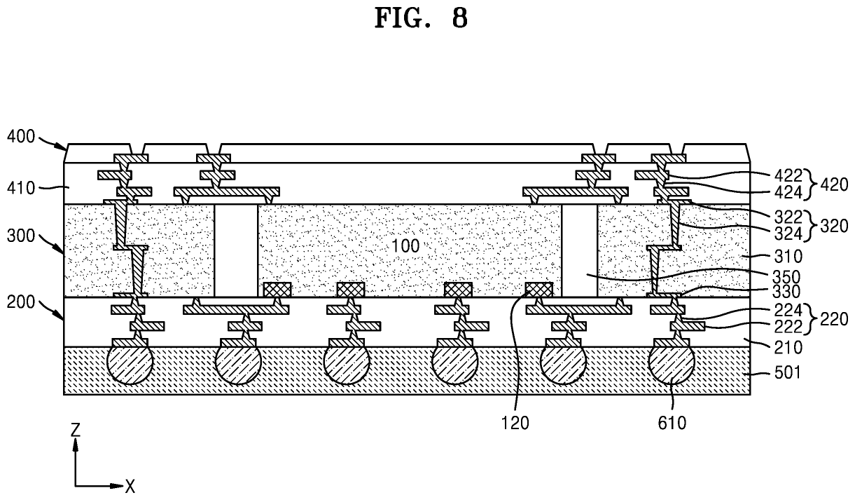

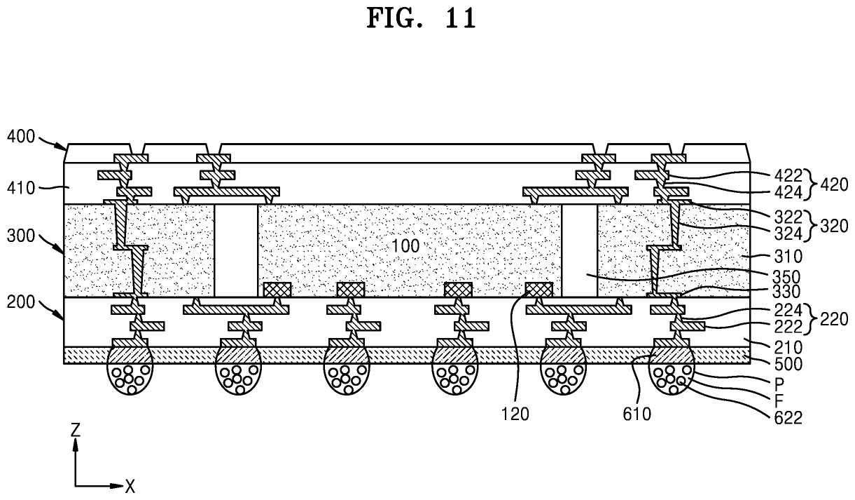

Referring to the example embodiment shown in FIG. 2, (A) illustrates the first solder ball 610 in a preliminary molding layer 501 in an operation of manufacturing the semiconductor package 10 to be described with reference to the example embodiment shown in FIG. 8. (B) illustrates a molding layer 500, which is ground, and the second solder ball 620 in an operation of completing the semiconductor package 10 described with reference to the example embodiment shown in FIG. 1. (C) illustrates a state in which the third solder ball 630 is attached to a lower surface of the first solder ball 610, which is ground, in an operation of manufacturing a semiconductor package to be described with reference to the example embodiment shown in FIG. 11.

Referring to (A) and (B) of the example embodiment shown in FIG. 2 together, the volume of the second solder ball 620 may be less than the volume of the first solder ball 610. A horizontal length R2 of the second solder ball 620 may be less than a horizontal length R1 of the first solder ball 610. A vertical height H2 of the second solder ball 620 may be less than a vertical height H1 of the first solder ball 610.

In example embodiments, the horizontal length R2 may be a length of a portion of the second solder ball 620, the portion having the largest width in a horizontal direction. In example embodiments, the horizontal length R1 may be a length of a portion of the first solder ball 610, the portion having the largest width in the horizontal direction. In example embodiments, in (A) and (B) of FIG. 2, the vertical height H1 may be a height of a portion of the first solder ball 610, the portion having the largest height in a vertical direction. The vertical height H2 may be a height of a portion of the second solder ball 620, the portion having the largest height in a vertical direction.

Referring to (A), (B) and (C) of the example embodiment shown in FIG. 2, the volume of the third solder ball 630 may be less than the volume of the first solder ball 610 and the volume of the second solder ball 620. A total volume of the first solder ball 610, which is ground, and the third solder ball, 630 may be the same as the volume of the second solder ball 620. In addition, as shown in (B) of the example embodiment shown in FIG. 2, the curvature of an inner side surface of a ball accommodating space 530 with respect to the second solder ball 620 may be greater than the curvature of the surface of the second solder ball 620.

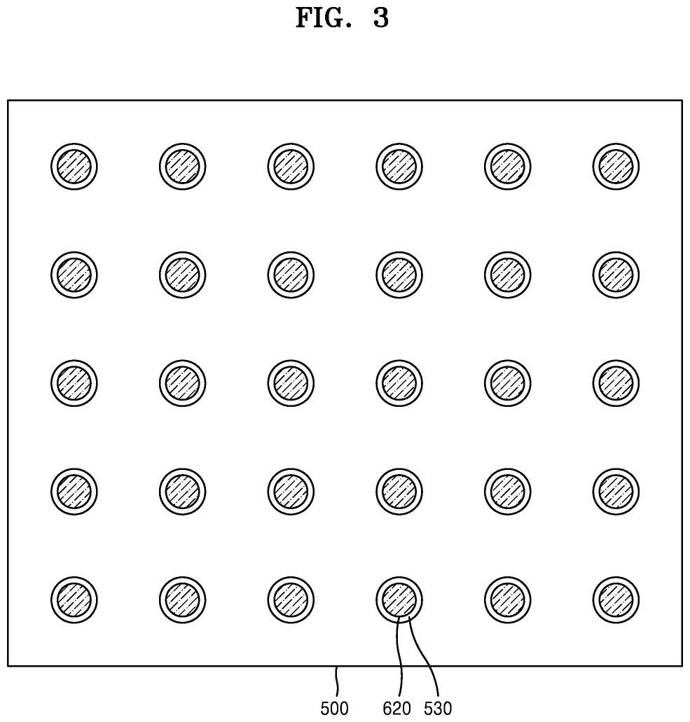

FIG. 3 is a diagram illustrating a bottom surface of a semiconductor package according to an example embodiment.

Referring to FIGS. 2 and 3, the second solder ball 620 may be spaced apart from the molding layer 500, which is ground, in a horizontal direction (e.g., an X direction). Here, the second solder ball 620 being spaced apart from the molding layer 500 includes a case where a portion of the second solder ball 620 is spaced apart from the molding layer 500 and a case where the second solder ball 620 is entirely spaced apart from the molding layer 500. The molding layer 500 may include the inner side surface of the ball accommodating space 530 surrounding a portion of the second solder ball 620. A gap may be between the inner side surface of the ball accommodating space 530 and the second solder ball 620. The gap between the inner side surface of the ball accommodating space 530 and the second solder ball 620 may have a horizontal width that reduces in a direction moving toward the lower redistribution layer 200. In addition, the gap between the inner side surface of the ball accommodating space 530 and the second solder ball 620 may have a horizontal width that increases in a direction moving away from the lower redistribution layer 200.

In example embodiments, the second solder ball 620 may be partially spaced apart from the molding layer 500, which is ground. For example, a portion of the second solder ball 620, the portion being vertically adjacent to the molding layer 500, may be in contact with the molding layer 500, and a remaining portion of the second solder ball 620, the portion not being in contact with the molding layer 500, may be spaced apart from the molding layer 500.

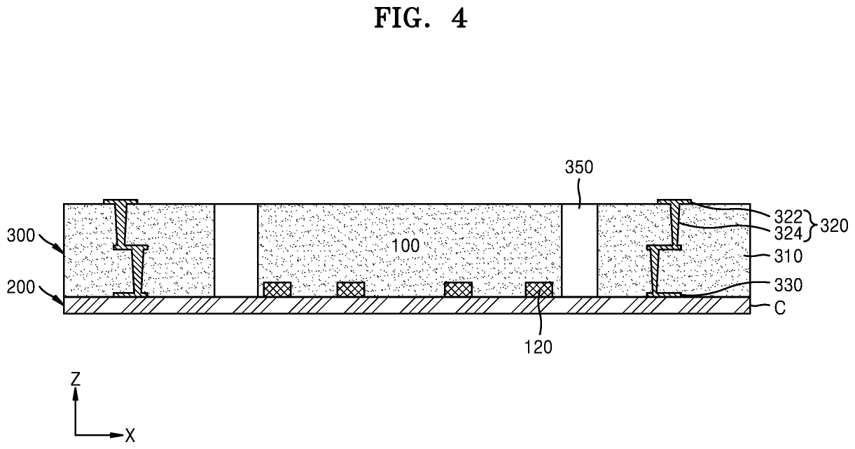

FIGS. 4, 5, 6, 7, 8, 9, 10 and 11 are cross-sectional views of a method of manufacturing the semiconductor package 10, according to an example embodiment. In particular, FIGS. 4, 5, 6, 7, 8, 9, 10 and 11 are cross-sectional views illustrating a method of manufacturing the semiconductor package 10 according to the example embodiments shown in FIG. 1, and FIGS. 4, 5, 6, 7, 8, 9, 10 and 11 are described with reference to the example embodiments shown in FIGS. 1 and 3 together.

Referring to a non-limiting embodiment shown in FIG. 4, the intermediate layer 300 is formed on a carrier substrate C to which a release film is attached.

The carrier substrate C may include any material having stability against a subsequent process or the like. In some example embodiments, when the carrier substrate C is to be separated and removed by laser ablation afterward, the carrier substrate C may be a transparent substrate. In some other example embodiments, when the carrier substrate C is to be separated and removed by heating afterward, the carrier substrate C may be a heat-resisting substrate. For example, the carrier substrate C may be a semiconductor substrate, a ceramic substrate, or a glass substrate, or the like.

In example embodiments, the carrier substrate C may include a heat-resisting organic polymer material, including, but not limited to polyimide (PI), polyetheretherketone (PEEK), poly(ethersulfone) (PES), poly(phenylene sulfide) (PPS), or the like.

At least one semiconductor chip 100 and the expansion structure 310 are attached on the carrier substrate C. In particular, the expansion structure 310 may be arranged on the carrier substrate C. Next, at least one semiconductor chip 100 may be attached on the carrier substrate C. Here, the semiconductor chip 100 may be attached on the carrier substrate C to be spaced apart from the expansion structure 310 in a horizontal direction.

Next, the sealing layer 350 covering the expansion structure 310 and the semiconductor chip 100 may be formed. In some example embodiments, the lower surface of the at least one semiconductor chip 100, the lower surface of the expansion structure 310, and the lower surface of the sealing layer 350 may be positioned at the same vertical level to form a coplanar surface with one another. The upper surface of the semiconductor chip 100 may be attached on the carrier substrate C to be positioned at a lower vertical level than that of the expansion structure 310. The semiconductor chip 100 may have a face-down arrangement in which the each of the plurality of chip connection pads 120 faces the carrier substrate C.

In example embodiments, the sealing layer 350 may be formed by using a thermosetting resin (e.g., an epoxy resin), a thermoplastic resin (e.g., PI), or a thermosetting resin or thermoplastic resin containing a reinforcing agent (e.g., an inorganic filler), specifically, an Ajinomoto build-up film (ABF), FR-4, BT, or the like. Alternatively, the sealing layer 350 may be formed by using a molding material (e.g., an EMC) or a photosensitive material (e.g., a photoimagable encapsulant (PIE)). In example embodiments, a portion of the sealing layer 350 may include an insulating material, including, but not limited to a silicon oxide film, a silicon nitride film, or a silicon oxynitride film.

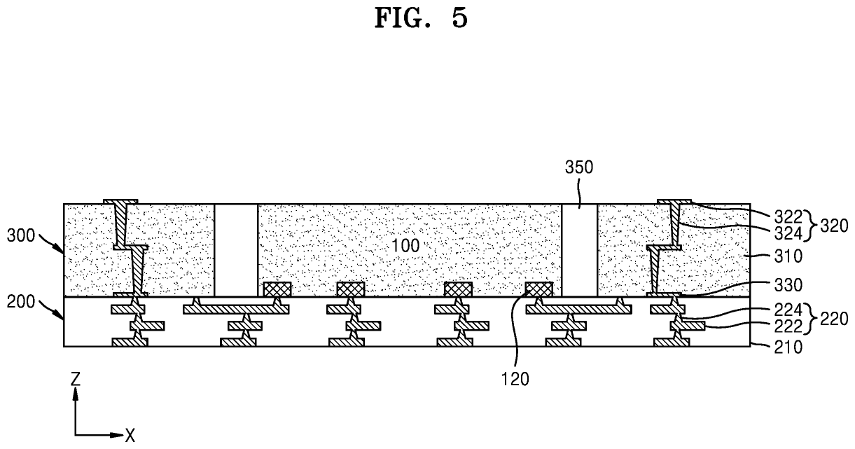

Referring to an example embodiment shown in FIG. 5, the carrier substrate C may be removed, and the lower redistribution layer 200 may be formed on a lower portion of the at least one semiconductor chip 100.

The lower redistribution layer 200 may include the lower redistribution insulating layer 210 and a plurality of lower redistribution conductive structures 220. In example embodiments, the lower redistribution layer 200 may include a plurality of lower redistribution insulating layers 210. The plurality of lower redistribution conductive structures 220 may include the plurality of lower redistribution line patterns 222 and the plurality of lower redistribution via patterns 224. Some of the plurality of lower redistribution line patterns 222, which are arranged on the upper surface of the lower redistribution layer 200, may be referred to as a plurality of first upper surface connection pads, and some of the plurality of lower redistribution line patterns 222, which are arranged on the lower surface of the lower redistribution layer 200, may be referred to as a plurality of first lower surface connection pads.

The lower redistribution layer 200 may be formed by a redistribution process. For example, the lower redistribution layer 200 may be formed by alternately forming the lower redistribution insulating layer 210 and the lower redistribution conductive structure 220. In some other example embodiments, the lower redistribution layer 200 may include a PCB.

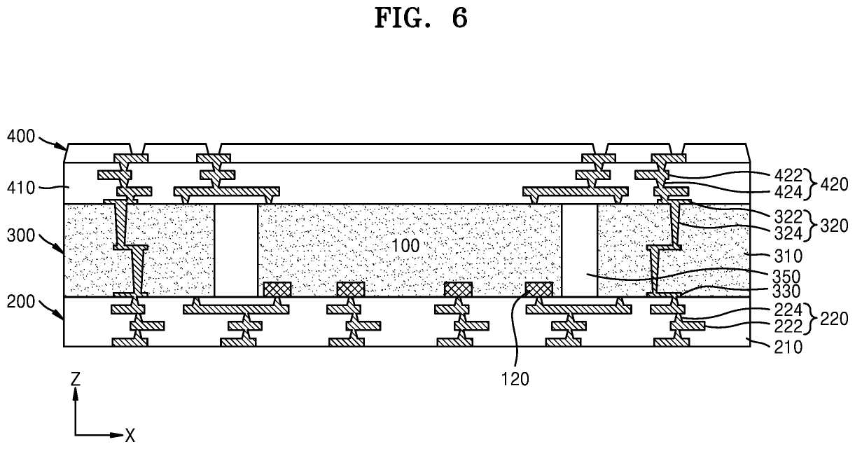

Referring to an example embodiment shown in FIG. 6, the upper redistribution layer 400 may be formed on an upper portion of the intermediate layer 300. The upper redistribution layer 400 may include the upper redistribution insulating layer 410 and the upper redistribution conductive structure 420. In some example embodiments, the upper redistribution layer 400 may include a plurality of upper redistribution insulating layers 410, which are stacked. A plurality of upper redistribution conductive structures 420 may include the plurality of upper redistribution line patterns 422 and the plurality of upper redistribution via patterns 424. Some of the plurality of upper redistribution line patterns 422, which are arranged on an upper surface of the upper redistribution layer 400, may be referred to as a plurality of second upper surface connection pads, and some of the plurality of upper redistribution line patterns 422, which are arranged on a lower surface of the upper redistribution layer 400, may be referred to as a plurality of second lower surface connection pads.

In some example embodiments, the upper redistribution layer 400 may be formed by a redistribution process. For example, the upper redistribution layer 400 may be formed by alternately forming the upper redistribution insulating layer 410 and the upper redistribution conductive structure 420. In some other example embodiments, the upper redistribution layer 400 may be a PCB.

Referring to an example embodiment shown in FIG. 7, the first solder ball 610 is formed on the lower redistribution layer 200.

The first solder ball 610 may be attached to at least some of the lower redistribution line patterns 222, which are arranged at the lowermost end in the lower redistribution layer 200 among the plurality of lower redistribution line patterns 222. A flux may be applied to the first solder ball 610. The flux is configured to improve adhesion between the first solder ball 610 and the lower redistribution line patterns 222. In addition, after the first solder ball 610 is adhered to the lower redistribution line patterns 222, a deflux may be performed on the first solder ball 610. Accordingly, the flux remaining on the first solder ball 610 may be removed.

Referring to an example embodiment shown in FIG. 8, the preliminary molding layer 501 covering the first solder ball 610 and the lower redistribution layer 200 may be formed on the lower surface of the lower redistribution layer 200.

The preliminary molding layer 501 may cover the lower surface of the lower redistribution layer 200 and the surface of the first solder ball 610. A remaining portion of the first solder ball 610, the remaining portion except for a portion in contact with the connection pad 330, may entirely be surrounded by the preliminary molding layer 501. In addition, the first solder ball 610 may be buried in the preliminary molding layer 501. In example embodiments, the preliminary molding layer 501 may include an insulating resin, including, but not limited to an EMC. In example embodiments, the molding layer 500 may further include a filler. The filler may be dispersed in the insulating resin. In example embodiments, the filler of the preliminary molding layer 501 may include, but is not limited to, metal powder or graphene powder, each of which has high thermal conductivity. In example embodiments, the filler of the preliminary molding layer 501 may include at least one of silica, alumina, zinc oxide, and nitrogen boride. The preliminary molding layer 501 may improve the thermal conductivity of the semiconductor package 10 by including alumina.

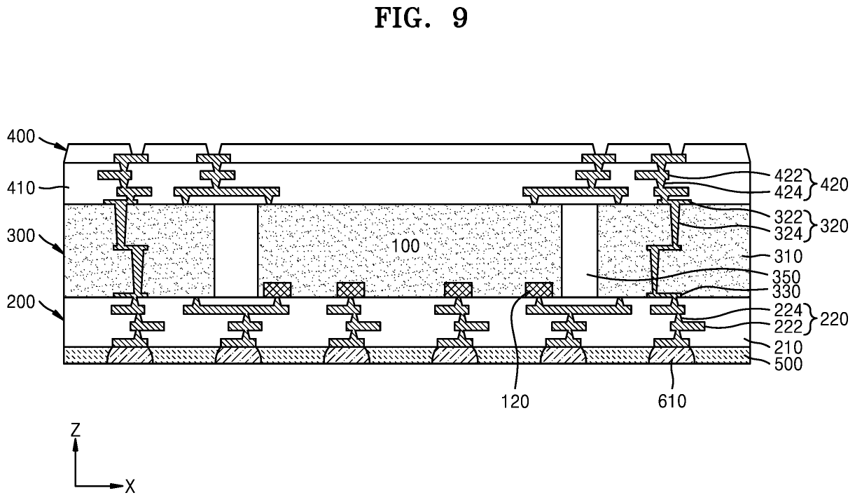

Referring to FIGS. 8 and 9, the preliminary molding layer 501 and the first solder ball 610 may each be ground.

A lower portion of each of the preliminary molding layer 501 and the first solder ball 610 may be removed by grinding the preliminary molding layer 501 and the first solder ball 610. The molding layer 500 may be formed by grinding the preliminary molding layer 501. In addition, a portion of the first solder ball 610 covered with the preliminary molding layer 501 may be exposed by grinding the preliminary molding layer 501 and the first solder ball 610. In example embodiments, grinding may be performed by using a diamond grinder or an equivalent thereof, but grinding is not limited thereto.

In example embodiments, the lowermost surface of the molding layer 500 and the lower surface of the first solder ball 610, which is ground, may be positioned on the same vertical level to form a coplanar surface with one another. In example embodiments, grinding of the preliminary molding layer 501 and the first solder ball 610 may be performed by grinding ¼ to ¾ of the vertical height of the first solder ball 610.

In example embodiments, a coefficient of thermal expansion (CTE) of the molding layer 500 may be determined based on a composite CTE. The composite CTE may be a value determined based on the CTE of each of the lower redistribution layer 200, the intermediate layer 300, and the upper redistribution layer 400. In example embodiments, the composite CTE may be an average value of the CTE of the lower redistribution layer 200, the CTE of the intermediate layer 300, and the CTE of the upper redistribution layer 400.

Here, a lower layer may include at least one of the lower redistribution layer 200 and the intermediate layer 300. An upper layer may include at least one of the intermediate layer 300 and the upper redistribution layer 400. The lower layer and the upper layer may be determined by the CTE and a thickness of each of the lower redistribution layer 200, the intermediate layer 300, and the upper redistribution layer 400.

In example embodiments, when the CTE of the lower layer is greater than the CTE of the upper layer, the CTE of the molding layer 500 may be formed to have a CTE equal to or less than the composite CTE. In example embodiments, when the CTE of the lower layer is less than the CTE of the upper layer, the CTE of the molding layer 500 may be formed to have a CTE equal to or greater than the composite CTE. In example embodiments, a difference between the composite CTE and the CTE of the molding layer 500 may be equal to or less than 10 PPM/° C. In example embodiments, a difference between the composite CTE and the CTE of the molding layer 500 may be equal to or less than 5 PPM/° C.

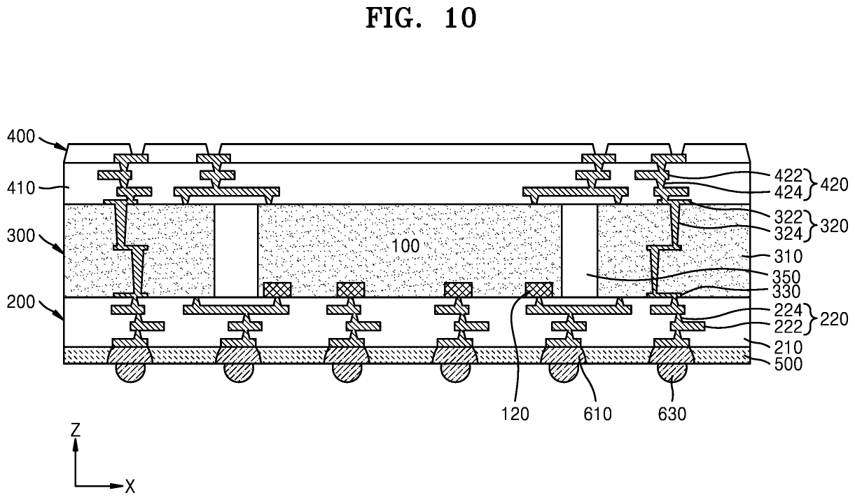

Referring to example embodiments shown in FIGS. 1 and 10, a solder paste P is applied on the first solder ball 610. The solder paste P may include a plurality of solder particles 622 and a flux. The plurality of solder particles 622 may each include the same or similar component as that of the first solder ball 610. In example embodiments, a total volume of the plurality of solder particles 622 may be less than a volume of a portion of the first solder ball 610 of the example embodiment shown in FIG. 8, the portion being ground in the example embodiment shown in FIG. 9.

The first solder ball 610 and the solder paste P may be reflowed to form the second solder ball 620. In example embodiments, the first solder ball 610 and the solder paste P may be heated to about 150° C. to about 250° C. Accordingly, the first solder ball 610 and the solder paste P may be formed into the second solder ball 620 having a spherical shape by surface tension.

The volume of the second solder ball 620 may be less than the volume of the first solder ball 610 according to the example embodiment shown in FIG. 8. Accordingly, a gap may be formed between the molding layer 500 and the second solder ball 620. The molding layer 500 may include the inner side surface of the ball accommodating space 530, the inner side surface facing the second solder ball 620.

In example embodiments, the inner side surface of the ball accommodating space 530 may surround a portion of the second solder ball 620. In example embodiments, the inner side surface of the ball accommodating space 530 may be concavely rounded toward a line layer (e.g., the lower redistribution layer 200 or the upper redistribution layer 400 of the example embodiment shown in FIG. 1). In example embodiments, the curvature of the inner side surface of the ball accommodating space 530 may be less than the curvature of the second solder ball 620. In example embodiments, the thickness of the molding layer 500 may be equal to or less than half the vertical height (e.g., in a Z direction of the example embodiment shown in FIG. 1) of the second solder ball 620. The lowermost surface of the molding layer 500 may be lower than the lowermost portion of the second solder ball 620.

Referring to example embodiments shown in FIGS. 1 and 11, in other example embodiments, the second solder ball 620 may be formed, according to the example embodiment, shown in FIG. 1 by bonding the third solder ball 630 to the first solder ball 610 according to the example embodiment shown in FIG. 9. The second solder ball 620 may be formed by reflowing the first solder ball 610 and the third solder ball 630.

In example embodiments, the first solder ball 610 and the third solder ball 630 may be heated to about 150° C. to about 250° C. Accordingly, the first solder ball 610 and the third solder ball 630 may be formed into the second solder ball 620 having a spherical shape by surface tension.

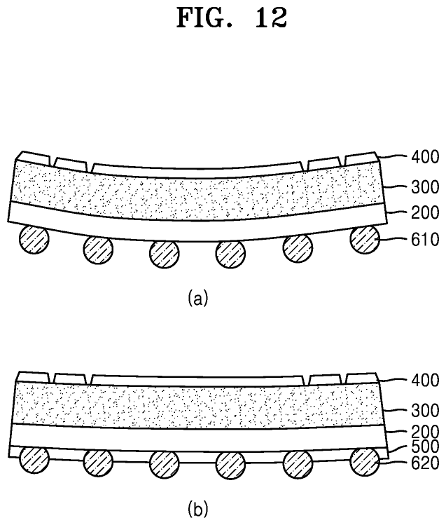

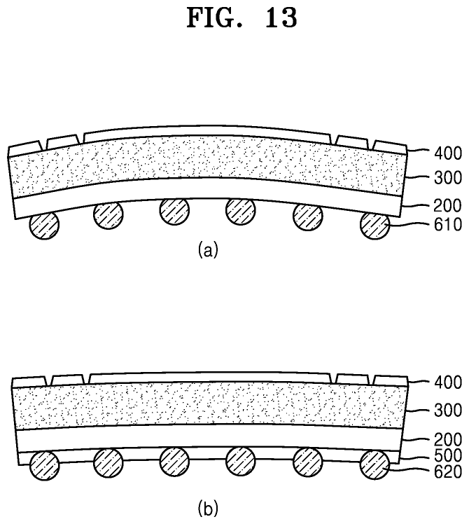

FIGS. 12 and 13 are diagrams illustrating an effect of preventing a warpage phenomenon according the CTE of the molding layer 500 of the semiconductor package 10 according to an example embodiment.

Referring to FIG. 12, FIG. 12(a) shows a comparative example in which warpage occurred in a semiconductor package. FIG. 12(b) shows the semiconductor package 10 in which the molding layer 500 has an adjusted CTE, according to an example embodiment.

(a) of FIG. 12 shows a case where the CTE of each of the upper redistribution layer 400 and the intermediate layer 300 is greater than the CTE of the lower redistribution layer 200 or a case where the CTE of the upper redistribution layer 400 is greater than the CTE of each of the intermediate layer 300 and the lower redistribution layer 200. Accordingly, the center of the semiconductor package is lower than the edge of the semiconductor package, and a warpage phenomenon having a concave shape occurred.

(b) of FIG. 12 shows an example embodiment comprising the semiconductor package 10 in which the molding layer 500 having a CTE lower than the composite CTE is formed on the lower surface of the lower redistribution layer 200 when the CTE of each of the upper redistribution layer 400 and the intermediate layer 300 is greater than the CTE of the lower redistribution layer 200 or when the CTE of the upper redistribution layer 400 is greater than the CTE of each of the intermediate layer 300 and the lower redistribution layer 200. Accordingly, the warpage phenomenon of (a) may be prevented. The molding layer 500 having an adjusted CTE is formed on the lower surface of the lower redistribution layer 200, and thus, the reliability of the semiconductor package may be improved.

Referring to FIG. 13, (a) shows a comparative example in which warpage occurred in a semiconductor package. (b) shows the semiconductor package 10 in which the molding layer 500 has an adjusted CTE, according to an example embodiment.

(a) of FIG. 13 shows a case where the CTE of each of the upper redistribution layer 400 and the intermediate layer 300 is less than the CTE of the lower redistribution layer 200 or a case where the CTE of the upper redistribution layer 400 is less than the CTE of each of the intermediate layer 300 and the lower redistribution layer 200. Accordingly, a warpage phenomenon in which the center of the semiconductor package rises more convexly than the edge of the semiconductor package occurred.

(b) of FIG. 13 shows an example embodiment comprising the semiconductor package 10 in which the molding layer 500 having a CTE lower than the composite CTE is formed on the lower surface of the lower redistribution layer 200 when the CTE of each of the upper redistribution layer 400 and the intermediate layer 300 is greater than the CTE of the lower redistribution layer 200 or when the CTE of the upper redistribution layer 400 is greater than the CTE of each of the intermediate layer 300 and the lower redistribution layer 200. Accordingly, the warpage phenomenon of (a) may be prevented. The molding layer 500 having an adjusted CTE is formed on the lower surface of the lower redistribution layer 200, and thus, the reliability of the semiconductor package may be improved.

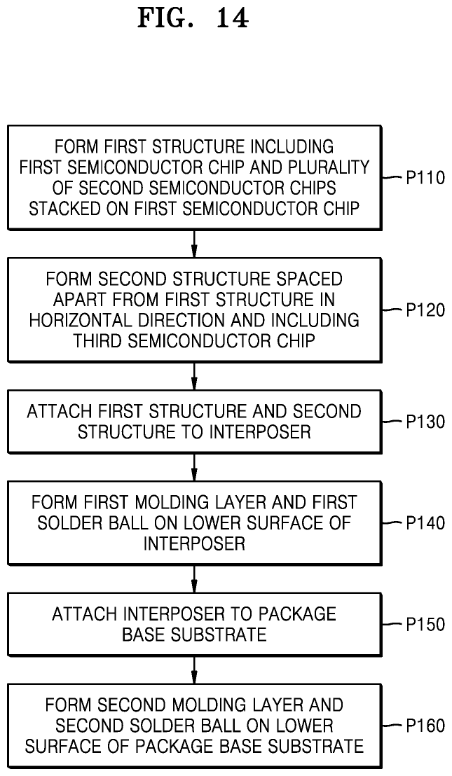

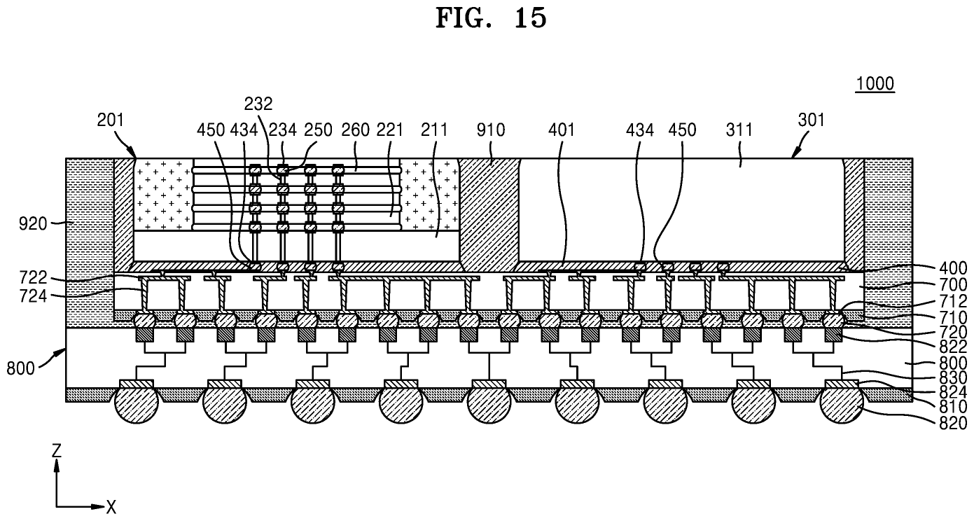

FIG. 14 is a flowchart illustrating a method of manufacturing a semiconductor package, according to an example embodiment. FIG. 15 is a cross-sectional view illustrating a semiconductor package 1000 according to example embodiments.

Referring to the example embodiments shown in FIGS. 14 and 15, in operation P110, a first structure 201 including a first semiconductor chip 211, and a plurality of second semiconductor chips 221 stacked on the first semiconductor chip 211 may be formed. The semiconductor package 1000 may include at least one first structure 201. The first structure 201 may be referred to as a memory stack. FIG. 15 illustrates an example embodiment wherein the first semiconductor chip 211 and four second semiconductor chips 221 are included, but example embodiments are not limited thereto.

The first structure may include the first semiconductor chip 211 and a plurality of second semiconductor chips 221. The first semiconductor chip 211 and the plurality of second semiconductor chips 221 may be DRAM. The first semiconductor chip 211 may include a test logic circuit, including, but not limited to a serial-parallel conversion circuit, a design for test (DFT), a joint test action group (JTAG), and a memory built-in self-test (MBIST), or a signal interface circuit, including, but not limited to a physical interface. The plurality of second semiconductor chips 221 may include, but is not limited to, a memory cell. For example, the first semiconductor chip 211 may be a buffer chip for controlling the plurality of second semiconductor chips 221. In some example embodiments, the first semiconductor chip 211 may not include a memory cell.

The plurality of second semiconductor chips 221 includes a plurality of connection pads 234 and a plurality of through electrodes 232. Some of the plurality of connection pads 234 may be upper surface connection pads, and the others may be lower surface connection pads. A chip connection terminal 250 may be formed between the upper surface connection pad and the lower surface connection pad. The chip connection terminal 250 may between the upper surface connection pad and the lower surface connection pad to electrically connect the first semiconductor chip 211 and the second semiconductor chip 221 to each other or to electrically connect the plurality of second semiconductor chips 221 to each other. The chip connection terminal 250 may be a bump, a solder ball, or the like. In some example embodiments, the second semiconductor chip 221 that is highest among the plurality of second semiconductor chips 221 may not include a through electrode.

An insulating adhesive layer 260 may be between each of the first semiconductor chip 211 and the plurality of second semiconductor chips 221. The insulating adhesive layer 260 may be attached to a lower surface of each of the plurality of second semiconductor chips 221 and may attach each of the plurality of second semiconductor chips 221 to a lower structure, for example, the first semiconductor chip 211 or another one of the second semiconductor chips 221 on a lower side among the plurality of second semiconductor chips 221. The insulating adhesive layer 260 may include, but is not limited to, a non-conductive film (NCF), a non-conductive paste (NCP), an insulating polymer, or an epoxy resin. The insulating adhesive layer 260 may surround the chip connection terminal 250 and fill a space between the first semiconductor chip 211 and each of the plurality of second semiconductor chips 221.

The first semiconductor chip 211 may have a horizontal width and an area greater than those of each of the plurality of second semiconductor chips 221. For example, the plurality of second semiconductor chips 221 may all overlap the first semiconductor chip 211 in a vertical direction.

Next, in operation P120, a second structure 301 spaced apart from the first structure 201 in a horizontal direction (e.g., an X direction) and including a third semiconductor chip 311 may be formed. The second structure 301 may include the third semiconductor chip 311. Here, the third semiconductor chip 311 may be referred to as a logic semiconductor chip. The third semiconductor chip 311 may include, but is not limited to, for example, one of a CPU chip, a GPU chip, an AP chip, an application specific integrated circuit (ASIC), or other processing chip.

In some example embodiments, the first semiconductor chip 211 may be a buffer chip for controlling high bandwidth memory (HBM) DRAM, and the plurality of second semiconductor chips 221 may each be a memory cell chip having cells of the HBM DRAM controlled by the first semiconductor chip 211. The first semiconductor chip 211 may be referred to as a buffer chip or a master chip, and the second semiconductor chip 221 may be referred to as a slave chip or a memory cell chip. A semiconductor package 10A including the first semiconductor chip 211 and the plurality of second semiconductor chips 221 sequentially stacked on the first semiconductor chip 211 may be referred to as an HBM DRAM device.

In operation P130, the first structure 201 and the second structure 301 may be attached to an interposer 700. The first structure 201 and the second structure 301 may be spaced apart from each other in the horizontal direction, and may be attached to the interposer 700. Here, the interposer 700 may be a redistribution layer (RDL) interposer. The interposer 700 may include a redistribution insulating layer, a plurality of redistribution line patterns 722, and a plurality of redistribution vias 724. Here, the semiconductor package 1000 may include a structural molding layer 910 surrounding the first structure 201 and the second structure 301, and a package molding layer 920 surrounding the interposer 700 and the structural molding layer 910. The structural molding layer 910 and the package molding layer 920 may form an EMC.

An underfill layer 401 surrounding a plurality of structural connection terminals 450 may be between the interposer 700 and the first structure 201. The underfill layer 401 may be formed of, but is not limited to, for example, an epoxy resin formed by a capillary under-fill method. The plurality of structural connection terminals 450 may respectively and electrically connect the plurality of pads 434 to each other.

In operation P140, a first molding layer 710 and a first solder ball 720 may be formed on the lower surface of the interposer 700. The first solder ball 720 may be electrically connected to one of metal pads 712 connected to the plurality of redistribution vias 724. The first solder ball 720 may be formed by reflowing a solder ball before grinding the first molding layer 710. In example embodiments, the diameter (e.g., R2 of the example embodiment shown in FIG. 2) of the first solder ball 720 may be any one value in a range of 0.8 to 0.95 times the diameter (e.g., R1 of the example embodiment shown in FIG. 2) of the solder ball. Here, the first molding layer 710 and the first solder ball 720 may respectively be formed in the same manner as the molding layer 500 and the second solder ball 620 in the example embodiment shown in FIGS. 7, 8, 9, 10 and 11. In addition, the first molding layer 710 may be the same as the molding layer 500 described with reference to the example embodiment shown in FIG. 1.

In operation P150, the interposer 700 may be attached to a package base substrate 800. The package base substrate 800 may include a plurality of board upper surface pads 822 and a plurality of board lower surface pads 824, which are respectively arranged on upper and lower surfaces of the package base substrate 800. The package base substrate 800 may include a plurality of board line paths 830 electrically connecting the plurality of board upper surface pads 822 and the plurality of board lower surface pads 824 to each other. In some example embodiments, the package base substrate 800 may be a PCB. For example, the package base substrate 800 may be a multi-layered PCB.

In operation P160, a second molding layer 810 and a second solder ball 820 may be formed on the lower surface of the package base substrate 800. The second solder ball 820 may be formed by reflowing a solder ball before grinding the second molding layer 810. In example embodiments, the diameter (e.g. R2 of the example embodiment shown in FIG. 2) of the second solder ball 820 may be any one value in a range of 0.8 to 0.95 times the diameter (e.g., R1 of the example embodiment shown in FIG. 2) of the solder ball. Here, the second molding layer 810 and the second solder ball 820 may respectively be formed in the same manner as the molding layer 500 and the second solder ball 620 in the example embodiments shown in FIGS. 7 to 11. In addition, the second molding layer 810 may be the same as the molding layer 500 described with reference to the example embodiment shown in FIG. 1.

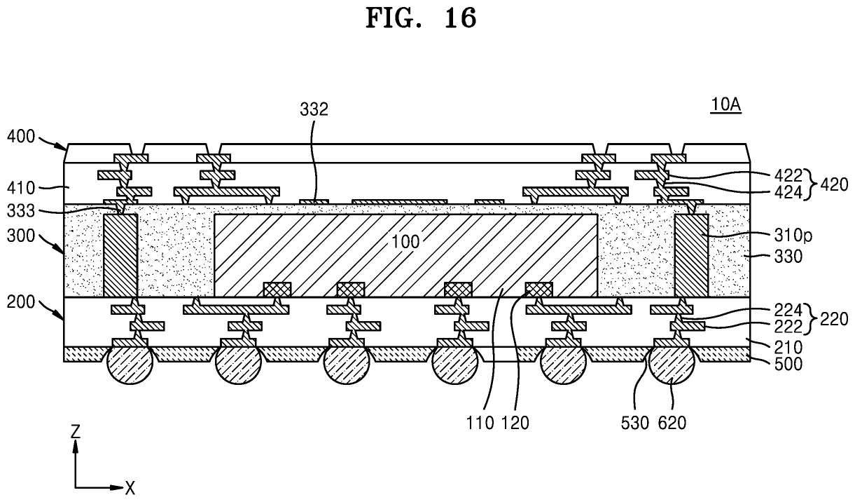

FIG. 16 is a cross-sectional view of a semiconductor package 10A according to an example embodiment.

Referring to an example embodiment shown in FIG. 16, the semiconductor package 10A according to an example embodiment may have a structure similar to that of the example embodiment shown in FIG. 1, except that the semiconductor package 10A has additional backside RDLs, each of which is connected to the upper redistribution layer 400. Descriptions of the components of the example embodiment may refer to descriptions of the same or similar components of the semiconductor package 10 according to the example embodiment shown in FIG. 1, unless otherwise specified.

The semiconductor package 10A according to the example embodiment has a structure that may be used as a package-on-package (POP) structure similar to the example embodiment shown in FIG. 1, but unlike the example embodiment shown in FIG. 1, the semiconductor package 10A may be a wafer level package (WLP). In the semiconductor package 10A, an interconnection element connecting the backside RDLs and the lower redistribution conductive structure 220 of the lower redistribution layer 200 to each other may be formed by using a vertical interconnection unit 310P, including, but not limited to a metal (e.g., copper).

The vertical interconnection unit 310P may be arranged through the intermediate layer 300 sealing the semiconductor chip 100 to electrically connect the backside RDLs and the lower redistribution layer 200 to each other. The backside RDLs may include a redistribution pattern 332 arranged on the intermediate layer 300 and a redistribution via 333 connecting the redistribution pattern 332 and the vertical interconnection unit 310P to each other. In an example embodiment, the vertical interconnection unit 310P is shown as an example of being directly connected to the redistribution via 333, but example embodiments are not limited thereto. In another example embodiment, the vertical interconnection unit 310P may be directly connected to the redistribution pattern 332.

While example embodiments have been particularly shown and described above, it will be apparent to those skilled in the art that various changes in form and details may be made therein without departing from the spirit and scope of the following claims.

What is claimed is:

1. A method of manufacturing a semiconductor package, the method comprising:
forming a first solder ball on a surface of a redistribution layer;
forming a preliminary molding layer on the surface of the redistribution layer and the first solder ball;
exposing the first solder ball and forming a molding layer by grinding the preliminary molding layer and the first solder ball; and
forming a second solder ball by reflowing the first solder ball,
wherein the second solder ball is spaced apart from the molding layer in a horizontal direction.

2. The method of claim 1, wherein the forming the second solder ball comprises:
applying a solder paste on an exposed surface of the ground first solder ball; and
reflowing the ground first solder ball and the solder paste,
wherein the solder paste comprises a plurality of solder particles and a flux, and
wherein a total volume of the plurality of solder particles is less than a volume of the ground first solder ball.

3. The method of claim 1, wherein the exposing the first solder ball is performed by grinding a portion of a vertical height of the first solder ball.

4. The method of claim 1, wherein a horizontal length of the second solder ball is less than a horizontal length of the first solder ball.

5. The method of claim 1, wherein the molding layer comprises an epoxy molding compound.

6. The method of claim 1, wherein a thickness of the molding layer is equal to or less than half of a vertical height of the second solder ball.

7. The method of claim 1, wherein the molding layer comprises an inner side surface of a ball accommodating space surrounding a portion of the second solder ball, and
wherein the inner side surface of the molding layer is concave and faces the redistribution layer.

8. The method of claim 7, wherein a curvature of the inner side surface of the molding layer is less than a curvature of a surface of the second solder ball.

9. The method of claim 1, further comprising forming the redistribution layer by performing a redistribution operation.

10. The method of claim 1, wherein the forming the second solder ball comprises:
forming a third solder ball on an exposed surface of the first solder ball; and
reflowing the first solder ball and the third solder ball, and
wherein a diameter of the third solder ball is less than a diameter of the first solder ball and a diameter of the second solder ball.

11. A method of manufacturing a semiconductor package, the method comprising:
attaching at least one semiconductor chip to a carrier substrate;
forming an intermediate layer covering an upper surface of the at least one semiconductor chip;
removing the carrier substrate;
forming a lower redistribution layer on a lower portion of the at least one semiconductor chip;
forming an upper redistribution layer on an upper portion of the intermediate layer;
forming a first solder ball on the lower redistribution layer;
forming a preliminary molding layer on a lower surface of the lower redistribution layer and on the first solder ball;
grinding the preliminary molding layer and the first solder ball;
applying a solder paste on the first solder ball; and
forming a second solder ball by reflowing the first solder ball and the solder paste,
wherein a volume of the second solder ball is less than a volume of the first solder ball.

12. The method of claim 11, wherein the preliminary molding layer comprises alumina (Al₂O₃).

13. The method of claim 11, wherein a coefficient of thermal expansion of the preliminary molding layer is greater than a composite coefficient of thermal expansion of the intermediate layer, the lower redistribution layer, and the upper redistribution layer.

14. The method of claim 11, wherein a vertical height of the second solder ball is less than a vertical height of the first solder ball.

15. The method of claim 11, wherein a coefficient of thermal expansion of the preliminary molding layer is less than a composite coefficient of thermal expansion of the intermediate layer, the lower redistribution layer, and the upper redistribution layer.

16. The method of claim 15, wherein a difference between the coefficient of thermal expansion of the preliminary molding layer and each of the composite coefficient of thermal expansion of the intermediate layer, the lower redistribution layer, and the upper redistribution layer is equal to or less than 5 PPM/° C.

17. The method of claim 11, the method further comprising:
grinding a molding layer from the preliminary molding layer,
wherein the molding layer comprises an inner side surface surrounding a portion of the second solder ball, and
wherein a curvature of the inner side surface of the molding layer is greater than a curvature of a surface of the second solder ball.

18. A method of manufacturing a semiconductor package, the method comprising:
forming a first structure comprising a first semiconductor chip and a plurality of second semiconductor chips stacked on the first semiconductor chip;
forming a second structure spaced apart from the first structure in a horizontal direction, the second structure comprising a third semiconductor chip;
attaching the first structure and the second structure to an interposer;
forming a first molding layer and a first solder ball on a lower surface of the interposer;
attaching the interposer to a package base substrate;
forming a second molding layer and a second solder ball on a lower surface of the package base substrate,
wherein each of the first molding layer and the second molding layer comprises an epoxy molding compound,
wherein the first solder ball is spaced apart from the first molding layer in the horizontal direction, and
wherein the second solder ball is spaced apart from the second molding layer in the horizontal direction.

19. The method of claim 18, wherein the first solder ball is formed by reflowing a solder ball before grinding the first molding layer, and
wherein a diameter of the first solder ball is in a range of 0.8 to 0.95 times a diameter of the solder ball.

20. The method of claim 18, wherein a thickness of the first molding layer is equal to or less than half a vertical height of the first solder ball, and
wherein a thickness of the second molding layer is equal to or less than half a vertical height of the second solder ball.
